(19) United States
(12) Patent Application Publication
(10) Pub. No.: US 2024/0168094 A1
(43) Pub. Date: May 23, 2024

(54) SYSTEMS, METHODS, AND MEDIA FOR PREDICTING DEGRADATION IN ENERGY STORAGE DEVICES

(71) Applicant: Davis George Moye, Tallahassee, FL (US)

(72) Inventor: Davis George Moye, Tallahassee, FL (US)

(21) Appl. No.: 18/390,034

(22) Filed: Dec. 20, 2023

Related U.S. Application Data
(63) Continuation of application No. 17/667,053, filed on Feb. 8, 2022.
(60) Provisional application No. 63/434,317, filed on Dec. 21, 2022.

(51) Int. Cl. G01R 31/367; G01R 31/374; G01R 31/3842

(52) U.S. Cl. CPC G01R 31/367; G01R 31/374; G01R 31/3842

(57) ABSTRACT

Systems, methods, and media for determining an energy storage device state of health are disclosed herein. The system can determine a first cycle time for an energy storage device; determine a first energy storage capacity for the energy storage device; determine a first electrolyte concentration for the energy storage device at the first cycle time; determine a second cycle time for the energy storage device; determine a second electrolyte concentration for the energy storage device at the second cycle time; and determine a degradation rate indicating an expected degradation of the energy storage device per cycle time unit based at least on: a first difference between the first electrolyte concentration and the second electrolyte concentration; and a second difference between the first cycle time and the second cycle time.

### CROSS-REFERENCE TO RELATED APPLICATIONS

This application claims priority to and the benefit of U.S. Provisional Patent Application No. 63/434,317 filed on Dec. 21, 2022, which is hereby incorporated by reference herein.

This application relates to U.S. application Ser. No. 17/667,053 filed on Feb. 8, 2022, now U.S. Patent Publication No. 2023/0251318 published on Aug. 10, 2023, which is hereby incorporated by reference herein.

### TECHNICAL FIELD

The embodiments described herein generally relate to systems, tools, methods and media for determining energy storage device degradation. Some embodiments generally relate to systems, tools, methods and media for determining battery, electrochemical capacitor, or other electrochemical energy storage device degradation in dynamic discharge and charge profiles, as well as in dynamic environmental conditions.

### BACKGROUND

Experimental work has provided significant insight into lithium-ion capacitor (LIC) performance. LICs couple anodic lithium (Li) ion intercalation, a key aspect of lithium-ion batteries (LIB), with cathodic lithium ion adsorption, characteristic of electrochemical capacitors (ELC). This enables LICs to exhibit both a Faradaic reaction, characteristic of a LIB, and a non-Faradaic reaction, characteristic of an ELC. LICs are thus hybrids between traditional LIBs and traditional ELCs. LICs often have higher specific power (10 kW·kg⁻¹) and longer cycle life (e.g. 300,000 cycles in laboratory experiments at General Capacitor) than most LIBs and higher specific energy (5-10 Wh·kg⁻¹) than most ELCs.

LICs' internal resistance may decrease at high temperatures. Solid electrolyte interphase (SEI) is a thin layer that forms on the anode's surface as lithium reacts with the electrolyte or impurities in the electrochemical energy storage cell. This SEI is essential to performance, as it enables the passage of lithium ions between the electrolyte and the electrodes' porous material. However, SEI growth can become too thick and thereby impede the intercalation of lithium ions into the negative electrode. This is a common degradation mechanism, which often leads to device failure.

Non-Faradaic mechanisms can and often do occur in LIBs and Faradaic mechanisms can and often do occur in ELCs, but in both cases these reactions are orders of magnitude smaller than the primary storage mechanism and are thus ignored. However, LICs and similar devices, known as asymmetric capacitors, noticeably employ both Faradaic and non-Faradaic storage mechanisms. Depending upon the balance designers seek between high energy storage and high charge or discharge current and cycle life, they may choose to employ proportionately more Faradaic or non-Faradaic reactions, respectively. Because LICs utilize both Faradaic and non-Faradaic reactions, they are great test platforms for studying new energy storage materials.

LICs typically employ both an anode capable of intercalation, as used in LIBs, and a cathode capable of adsorption, as used in ELCs. Intercalation enables more energy storage but is slower and less reversible than adsorption. A common ELC electrode material is activated carbon, which typically stores charge via an ion adsorption method. The present inventor has significant experience designing activated carbon (AC) and graphite electrodes to describe LICs, removing uncertainty in that variable, and the LIC structure exaggerates the imbalances between Faradaic and non-Faradaic behavior in an electrochemical cell. Therefore, LICs are good tools for understanding energy storage device dynamics.

The disclosed system and method may predict the long-term degradation of a LIB under dynamic charge or discharge profiles.

### SUMMARY

This summary is provided to introduce a variety of concepts and/or aspects in a simplified form that is further disclosed in the detailed description, below. This summary is not intended to identify key or essential inventive concepts of the claimed subject matter, nor is it intended for determining the scope of the claimed subject matter.

A system of one or more computing devices can be configured to perform particular processes by virtue of having software, firmware, hardware, or a combination thereof installed on the system that in operation causes or cause the system to perform the processes. One or more computer applications can be configured to perform particular processes by virtue of including instructions that, when executed by one or more processors, cause the one or more processors to perform the processes.

In a general aspect, a system for determining an energy storage device state of health, can include memory; and one or more processors configured at least to: determine a first cycle time for an energy storage device; determine a first value indicating a first energy storage capacity for the energy storage device at the first cycle time; determine a first electrolyte concentration for the energy storage device at the first cycle time; determine a second cycle time for the energy storage device, the second cycle time being different than the first cycle time; determine a second value indicating a second energy storage capacity for the energy storage device at the second cycle time; determine a second electrolyte concentration for the energy storage device based at least on: the first electrolyte concentration; the first value indicating the first energy storage capacity; and the second value indicating the second energy storage capacity; and determine a degradation rate indicating an expected degradation of the energy storage device per cycle time unit based at least on: a first difference between the first electrolyte concentration and the second electrolyte concentration; and a second difference between the first cycle time and the second cycle time.

In a general aspect, a method for determining an energy storage device state of health, can include determining a first cycle time for an energy storage device; determining a first value indicating a first energy storage capacity for the energy storage device at the first cycle time; determining a first electrolyte concentration for the energy storage device at the first cycle time; determining a second cycle time for the energy storage device, the second cycle time being different than the first cycle time; determining a second value indicating a second energy storage capacity for the energy storage device at the second cycle time; determining a second electrolyte concentration for the energy storage device based at least on: the first electrolyte concentration; the first value indicating the first energy storage capacity; and the second value indicating the second energy storage capacity; and determining a degradation rate indicating an expected degradation of the energy storage device per cycle time unit based at least on: a first difference between the first electrolyte concentration and the second electrolyte concentration; and a second difference between the first cycle time and the second cycle time.

In a general aspect, a non-transitory computer-readable medium can comprise instructions, that when executed by one or more processors, cause the one or more processors to perform a method for determining an energy storage device state of health, the method comprising determining a first cycle time for an energy storage device; determining a first value indicating a first energy storage capacity for the energy storage device at the first cycle time; determining a first electrolyte concentration for the energy storage device at the first cycle time; determining a second cycle time for the energy storage device, the second cycle time being different than the first cycle time; determining a second value indicating a second energy storage capacity for the energy storage device at the second cycle time; determining a second electrolyte concentration for the energy storage device based at least on: the first electrolyte concentration; the first value indicating the first energy storage capacity; and the second value indicating the second energy storage capacity; and determining a degradation rate indicating an expected degradation of the energy storage device per cycle time unit based at least on: a first difference between the first electrolyte concentration and the second electrolyte concentration; and a second difference between the first cycle time and the second cycle time.

### BRIEF DESCRIPTION OF THE DRAWINGS

A complete understanding of the present embodiments and the advantages and features thereof will be more readily understood by reference to the following detailed description, appended claims, and accompanying drawings, wherein:

FIG. 1 illustrates an Randles equivalent circuit used in the determination of instantaneous voltage in the time domain;

FIG. 2 illustrates how the Warburg components are found in a Randles equivalent circuit model;

FIG. 3 is a similar illustration as FIG. 2, illustrating how the Warburg components are found in a Randles equivalent circuit model;

FIG. 4 illustrates a simplified flowchart of a use case diagram according to some embodiments described herein;

FIG. 5 illustrates a block diagram of a system or method of determining energy storage device state of charge as a function of changing voltage;

FIG. 6 illustrates a block diagram of a system or method of determining energy storage device state of charge as a function of changing voltage;

FIG. 7 illustrates a block diagram of a computing device according to some embodiments described herein;

FIG. 8 illustrates a charge and discharge profile generated by a system or method designing an energy storage device according to some embodiments described herein;

FIG. 9 illustrates an energy storage profile generated by a system or method designing an energy storage device according to some embodiments described herein;

FIG. 10 illustrates an energy storage profile generated by a system or method designing an energy storage device according to some embodiments described herein;

FIG. 11 illustrates a flow diagram of a process for determining an energy storage device's state of health according to some embodiments described herein;

FIG. 12 illustrates a flow diagram of a process for applying the findings of a regression analysis determine an energy storage device's state of health, according to some embodiments described herein;

FIG. 13 illustrates a block diagram of a system for verifying the energy storage capacity of an energy storage device according to some embodiments described herein; and

FIG. 14 illustrates a regression analysis performed for an energy storage device according to some embodiments described herein.

The drawings are not necessarily to scale, and certain features and certain views of the drawings may be shown exaggerated in scale or in schematic in the interest of clarity and conciseness.

### DETAILED DESCRIPTION

The specific details of the single embodiment or variety of embodiments described herein are to the described apparatus. Any specific details of the embodiments are used for demonstration purposes only, and no unnecessary limitations or inferences are to be understood therefrom.

Before describing the exemplary embodiments in detail, it is noted that the embodiments reside primarily in combinations of components and procedures related to the apparatus. Accordingly, the apparatus components have been represented where appropriate by conventional symbols in the drawings, showing only those specific details that are pertinent to understanding the embodiments of the present disclosure so as not to obscure the disclosure with details that will be readily apparent to those of ordinary skill in the art having the benefit of the description herein.

The specific details of the single embodiment or variety of embodiments described herein are set forth in this application. Any specific details of the embodiments are used for demonstration purposes only, and no unnecessary limitation or inferences are to be understood therefrom. Furthermore, as used herein, relational terms, such as “first” and “second,” “top” and “bottom,” and the like, may be used solely to distinguish one entity or element from another entity or element without necessarily requiring or implying any physical or logical relationship, or order between such entities or elements.

As used herein, “energy storage device,” “battery,” or “capacitor,” and variations on those terms are used generally to refer to device(s) that store energy physically or chemically and may include one or more batteries, electrochemical capacitors (e.g., supercapacitors, asymmetric capacitors, electrochemical double layer capacitors), any other energy storage device used across a variety of applications, or any combination thereof.

A system, method, and media for designing an energy storage device as a function of size, constituent components, materials, and operating conditions is disclosed. The system may determine a dynamic state of charge of a virtual or planned to-be-built energy storage device based on determining energy storage as a function of charge or discharge current and constituent components. The system, method, and media may account for various factors including, but not limited to, desired energy storage device materials, size, and operating conditions. In some embodiments, the system, method, and media can account for at least a change (e.g., decrease) in electrolyte concentration as the energy storage device charges and discharges over time. As the electrolyte concentration of the energy storage device decreases over time, the ionic conductivity of the energy storage device decreases over time. In some embodiments, the systems, methods, and media can account for at least a change (e.g., decrease) an electrode's effective surface area as the energy storage device charges and discharges over time. As the energy storage device charges and discharges over time, one or more electrodes of the energy storage device can be covered with dendrites, which reduces the electrode's effective surface area and reduces the energy storage device's ability to store a charge. An electrode effective surface area of the energy storage device can include an effective surface area of any anode(s) of the energy storage device, an effective surface area of any cathode(s) of the energy storage device, or any combination thereof.

As a non-limiting example, a system or method for designing an energy storage device as a function of size, constituent components, materials, and operating conditions may include predicting an energy storage device's energy storage as a function of the energy storage device's charge or discharge current and constituent components. The system and method may determine dynamic state of charge based on computed energy storage as a function of the energy storage device's charge or discharge current and constituent components. The system and method may be implemented in a set of computer-executable components or algorithms configured for determining dynamic state of charge in a battery or electrochemical capacitor.

The system or method for designing an energy storage device as a function of size, components, and operating conditions may include receiving component information relating to an energy storage device's charge or discharge current and constituent components. Constituent components with their common technical variables, as appropriate, can include electrode density (ρ), active layer porosity (ϵ), metal current collector density, separator thickness (Iₛ), intercalation rate constant (k), specific capacitance of anode electrode (C_{b}), initial concentration of intercalation material in the electrode material (C_{T}), initial concentration of electrolyte (Cᵢ), effective conductivity of electrode material (σ), specific surface area of the anode electrode (αₐ) and specific surface area of the cathode electrode (α_{c}). Another initial input variable is effective particle radius (r_{eff}), which, if divided by five, gives an initial Nernst diffusion radius (δ),

$$δ = \frac{{r}_{eff}}{5}$$

Nernst diffusion radius increases during a charge or discharge cycle, but an average value may be used for sufficiently accurate computations.

As a non-limiting example, a virtual or to-be-built energy storage device may be designed based on desired properties or desired operating conditions, such as, but not limited to, dynamic state of charge, degradation rate, performance at a certain temperature(s), expected life cycle, or the like. As a non-limiting example, dynamic state of charge, degradation rate, performance at a certain temperature(s), expected cycle life, or the like may inform selection of an energy storage devices components, size, or materials.

The system or method of designing an energy storage device as a function of size, constituent components, and operating conditions may include receiving user inputs including electrode density (ρ), active layer porosity (ϵ), metal current collector density, separator thickness (Iₛ), intercalation rate constant (k), specific capacitance of electrode (C_{b}), initial concentration of intercalation material in the electrode material (C_{T}), initial concentration of electrolyte (Cᵢ), effective conductivity of electrode material (σ), specific surface area of the anode electrode (αₐ), specific surface area of the cathode electrode (α_{c}), effective particle radius (r_{eff}), or Nernst diffusion radius (δ). In some cases, inputs may be calculated, such as Nernst diffusion radius (δ) shown above.

Alternatively, the system or method of designing an energy storage device as a function of size, constituent components, and operating conditions may include receiving user inputs of desired components' physical properties, operating temperature, charge power and therefore current, and instantaneous voltage. Voltage may also be dynamically computed by the system, which considers voltage changes as a function of Faradaic energy storage, non-Faradaic energy storage, and Ohmic losses. Dynamic voltage changes computed by the system indicate state of charge. The contributions of Faradaic, non-Faradaic, and Ohmic properties to state of charge indicate the energy stored or discharged from battery reactions, electrochemical capacitor reactions, and energy lost to heat.

The system and method of determining dynamic state of charge in an energy storage device may include determining energy storage, E, as a function of the energy storage device's charge or discharge current and constituent components according to:

E=½CΔV²

Where E is energy stored by the energy storage device in Watt-hours, C is capacitance in Farads, and ΔV is the change in the energy storage device's voltage over a complete charge or discharge, measured in volts. In this method, the system computes energy stored from the Faradaic and non-Faradaic processes, respectively, and the energy lost to heat in an energy storage device. The system may also compute power, P, according to:

$$P = \frac{{V}^{2}}{R}$$

Where V is voltage used to charge or discharge the energy storage device and R is the impedance or resistance of the energy storage device.

The disclosed system or method includes a multiphysics-based energy storage device design tool intended to dynamically and accurately model a energy storage device's long-term performance, especially its long-term degradation, as a function of its constituent materials and operating conditions.

The disclosed system and method include the application of recent research on energy storage devices' cycle life in order to determine the long-term degradation of an energy storage device under a dynamic charge or discharge profile as a function of a energy storage device's constituent materials and operating conditions. This will be done through a multiple step process disclosed herein, which can be repeated for each time step during a simulated charge or discharge cycle.

The disclosed system or method may use a multi-physics tool to generate a Randles equivalent circuit that models, with high accuracy (>96%), how the operating current interacts with the electrolyte, lithium ions, and electrodes in a non-degraded energy storage device. Available modeling tools derive these values experimentally from finished devices, i.e. no other commercial providers begin with a physics-based model of the materials' performance.

The system or method may employ an Arrhenius equation to model how irregular charge or discharge profiles degrade energy storage devices over time. This effect is normally clearly defined in the laboratory but is poorly defined in real life. The disclosed system or method will consider the effects of these unclear cycles and their discretized impacts on energy storage.

This is possible by quantifying the effects of cycle current based at least upon activation energy, therefore based upon a degradation rate, and therefore based upon either the available quantity of charge-carrying ions, i.e. the resulting new electrolyte concentration (cₛ) or upon the electrode's concentration in intercalation material of the electrode material (c_{T}), a measure of the electrode's material's capacity to store energy-carrying ions. The outcomes of this step will be then inputted to the first step as a new initial electrolyte concentration (cₛ) and will repeat the process, modeling how the battery's energy storage performance will be affected over cycle time. Cycle time can refer to an amount of time in which an energy storage device was cycled (e.g., one or more minutes, hours, days, months, years, etc.), a count of cycles (e.g., one cycle, two cycles, three cycles, etc.), or a combination thereof. Cycling an energy storage device can include charging the energy storage device any suitable number of times and then discharging the energy storage device by an amount that is at least approximately equal to an energy storage capacity of the energy storage device. For example, a single cycle can include charging the energy storage device to its energy storage capacity and then completely discharging the energy storage device.

The system and method may include a long-term modeling accuracy of >85% after four cycles for all types of energy storage devices, including LIBs, LICs, and for known and unknown designs, while existing competitors can only reach 60%, and only for non-degraded devices with previously studied designs. The reason for this is that leading competitors are either data analytics tools or do not rely upon the physical processes inside the LIB or LIC cell. This modeling capability represents a clear step beyond the state of the art, as it will be the only approach that takes into account the multiple physics phenomena occurring inside a battery cell, especially how the ever-changing charge or discharge current degrades energy storage.

The disclosed system or method will enable developers to optimize LIB prototyping, eliminating much guesswork from the R&D process, thereby drastically reducing costs and time to market. Even the basic modeling tool alone can reduce materials and labor costs of developing a new LIB by 50-80%. Moreover, thanks to accurate simulations, the disclosed system or method will permit the basic modeling and design tool to assess a device's long-term value without needing to spend months and even years in cycle life testing process.

The disclosed system or method may take numerous input variables related to electrode architecture (e.g. anode electrode thickness, area, porosity, intercalation properties, etc.). The disclosed system or method will use novel modifications to the Butler-Volmer equation, Fick's Law, and the Randles equivalent circuit model, among others, to predict how the operating current of an electrochemical cell interacts with the electrolyte, lithium ions, and electrodes in a LIB or a LIC. With this data, the effect these variables have on the exchange current and overall temperature of the cell can be calculated, as well as their effects upon the Warburg elements, the double layer and charge transfer elements, and series resistance from Joule heating. Then, the disclosed system or method will determine and quantify the Faradaic, battery-like, energy storage, the non-Faradaic, capacitor-like, energy storage, and any resistive losses in the cell.

This capability is based on recent research, which indicates that energy storage device degradation (e.g., LIBs and many energy storage devices) can be described as:

$$k = \frac{{D}_{T}}{b} ,$$

where k is the cell's reaction rate constant, b is a degradation constant, and D_{T} is the degradation rate that, in some embodiments, can be defined as

$${D}_{T} = \frac{{c}_{i} - {c}_{f}}{t} ,$$

where cᵢ is the initial electrolyte concentration, c_{f} is the final electrolyte concentration, and t is the time interval between them. Thus, D_{T} can be expressed as

$${D}_{T} = {A}_{D} {e}^{- \frac{{E}_{a}}{RT}} ,$$

where R is the universal gas constant, T is the absolute cell temperature, and Eₐ is the cell reaction's activation energy. It has been determined that i∝k for reasons unrelated to T, where i is current applied to charge or discharge the energy storage device. In some embodiments, since i∝k, b can be redefined as

$$b = \frac{{D}_{T}}{i}$$

so that the degradation ratio can be determined as

$${D}_{T} = ib = \frac{{c}_{i} - {c}_{f}}{t}$$

and therefore, c_{f}=cᵢ−tib. As the disclosed system or method continuously computes the current i throughout a charge or discharge cycle, it can be modified to compute Eₐ as well. Once this has been accomplished, the disclosed system or method can be modified to compute k, the D_{T} after any specified length of time, or the time required to degrade to any storage capacity.

Based on the above information, the following computation can be performed: D_{T}=ib, where b is a constant. Consequently,

$${E}_{a} = - RT ln ( \frac{{D}_{T}}{{A}_{D}} )$$

and

$${c}_{f} = {c}_{i} - {tA}_{D} {e}^{\frac{- {E}_{a}}{RT}} .$$

The initial electrolyte concentration cᵢ can be determined to be 100% of cₛ. The final electrolyte concentration c_{f} can be determined by determining a percentage, and multiplying the percentage by cₛ to compute a new cₛ, which will be used as a new cᵢ during the next computation. Ultimately, this results in an Arrhenius degradation curve i.e., Eₐ is a term that changes with current, and instantaneous current changes will cause instantaneous changes to Eₐ. Specifically, we have found that

$${E}_{a} = - RT ln ( \frac{ib}{{A}_{D}} ) ,$$

and therefore c_{f}=cᵢ−tib, where b decreases as t increases until tib≈0. As c_{f} decreases, the disclosed system or method must be adjusted to account for the change in the next charge or discharge time step. Although the reasons for cell degradation may vary, they all assume that either the maximum number of ions able to intercalate decreases or that the electrode can intercalate fewer ions. The disclosed system or method will account for this by accordingly lowering maximum cₛ every iteration by using the computed c_{f} value as the new cᵢ for every subsequent iteration. Sometimes degradation may be reflected by a change in effective surface area (SA) rather than cᵢ and c_{f}. The amount degradation affects cᵢ and c_{f} or SA is determined by the user and is based upon external knowledge of the energy storage chemistry's common degradation mechanisms.

The disclosed system or method will calculate the expected energy storage as:

$${E}_{stored} = \frac{1}{2} {C}_{T} {ΔV}^{2} ,$$

where ΔV is the change in voltage during charge or discharge and C_{T} is the total capacitance. The energy stored in the energy storage device after charging the energy storage device at a first time can be proportional to an initial electrolyte concentration, i.e., Eᵢ∝cᵢ at the first time and the energy stored in the energy storage device after charging the energy storage device at a second time can be proportional to a final electrolyte concentration, i.e., E_{f}∝c_{f} at the second time, wherein the second time is different from the first time. Accordingly,

$$\frac{{c}_{i}}{Ei} = \frac{{c}_{f}}{Ef}$$

so that the final electrolyte concentration can be determined as

$${c}_{f} = \frac{{c}_{i} {E}_{f}}{{E}_{i}} .$$

C_{T} is calculated as C_{T}=C_{W}+C_{dl}, where C_{W} is the Warburg capacitance, created by Faradaic behavior in the cell, and C_{dl} is the double layer capacitance, created by non-Faradaic behavior. C_{dl} depends upon the density of the electrode material (ρ), mass of the active material (M), porosity of the electrode material (ϵ), thickness of the electrode (l) and thickness of the separator material between the electrodes (lₛ), as follows:

$${C}_{dl} = \frac{{F}_{ρ l}}{2 M} ( 1 - ε ) \frac{l}{{l}_{S}} .$$

ΔV is computed as the change in the sum of all voltage drops across all resistive elements (V_{T}), as follows:

V_{T}=V_{W}+V_{ct//dt}+Vₛ

wherein V_{W} is the drop across the Warbug elements, V_{ct//dt} is the drop across the charge transfer and double layer elements, and V_{S} is the drop across purely resistive elements. Ohm's law gives the power used during the total charge or discharge as P=IV_{T}, and the energy required to do this from the time required for the charge or discharge (E_{req}), E_{req}=∫Pdt. Losses during the charge or discharge (Eₗₒₛₜ), can be computed from the difference between E_{stored} and E_{req}, as follows:

Eₗₒₛₜ=E_{req}−E_{stored}

All variables contained in the C_{dl} equation are unique to their specific energy storage device material and architecture but vary with current, voltage, and several other operating parameters. Please note this calculation compares M with ϵ. As previously said, to date many studies have not accounted for the relationship between electrode porosity and electrode mass.

The disclosed system or method accounts for this relationship using the Faradaic Charge Storage equation:

$${C}_{W} = \frac{{c}_{i} {R}_{W}^{2} {F}^{2} SAl}{2 RT} ,$$

where C_{W} is Warburg capacitance, R_{W} is Warburg impedance, F is Faraday's constant, SA is the effective surface area, l is the electrode thickness, and T is the internal temperature increase of the energy storage device. T can be found from the Butler-Volmer equation:

$${i}_{d} = {i}_{o} ( {e}^{\frac{{α}_{a} nF}{RT} η} - {e}^{\frac{{α}_{c} nF}{RT} η} ) ,$$

where i_{d} is current density, i₀ is the exchange current density, η is the electrode surface overpotential, αₐ and α_{c} are the specific surface areas of the electrodes, n is the number of moles of electrons reduced or oxidized per mole of charge carrier, and other variables are as previously defined. i₀ can be computed as a function of the intercalation rate constant of the electrode material (k), the specific capacitance of the electrode (C_{b}), αₐ and α_{c}, c_{T}, and the ionic concentration of the electrolyte (c_{S}) as follows:

i₀=kC_{b}^{a}^{ₐ}(c_{T}−c_{S})^{a}^{ₐ}c_{S}^{a}^{_{c}}.

Cₛ is computed by:

$${c}_{S} = \int \frac{{dD}_{S} {dc}_{S}}{{( dr )}^{2}} dt ,$$

where D_{S} is the ionic diffusion coefficient, dr is the thickness of the anode, and dt is the charge time. D_{S} can be found from the equation:

$${D}_{S} = \frac{{R}^{2} {T}^{2}}{2 {n}^{4} {F}^{4} {A}^{2} {c}_{i}^{2} σ} ,$$

wherein σ is the solid phase conductivity of the ionic material.

In summary, the disclosed system or method amalgamates the relationships between R_{w}, R_{ct}, C_{dl}, C_{w}, and other variables, then outputs highly accurate predictions for energy storage (E) in Wh and voltage (V_{T}), as the sum of voltage across Warburg (V_{w}), capacitive elements (V_{ct//dt}), and any series resistors (V_{S}). By combining all these relationships, and by calculating the Faradaic energy storage and the non-Faradaic capacitive energy storage in the cell, indicated by contributions of V_{w} and V_{ct//dt}, respectively, to V_{T}, the disclosed system or method will output a good prediction of the energy storage device's capacity and therefore degradation with high certainty.

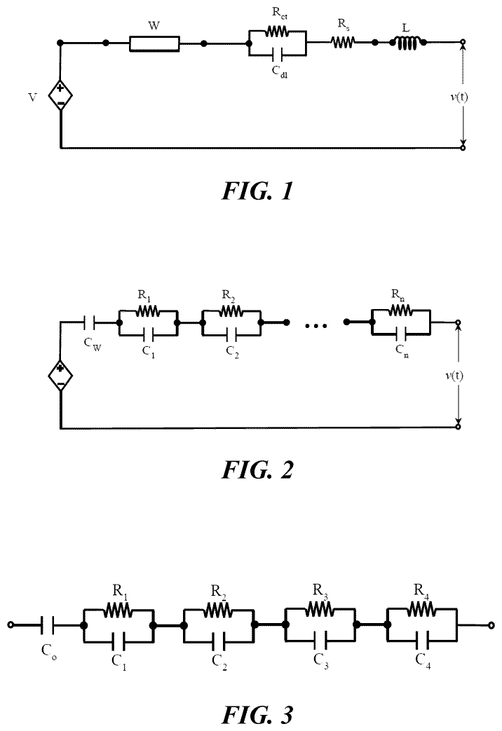

In FIG. 1, a Randles equivalent circuit used to model in the time domain is illustrated. A Warburg element (W) is in series with a parallel charge transfer resistance (R_{ct}) and double layer capacitance (C_{dl}), series resistance (R_{S}), and inductor (L).

In FIG. 1, W represents Warburg elements i.e., a measure of charge transfer kinetics in the energy storage device, R_{ct} is the charge transfer resistance, C_{dl} is the double layer capacitance, Rₛ is the series resistance, and L is the inductance.

W in FIG. 1 may be expanded as shown in FIG. 2 or FIG. 3.

Instantaneous voltage, expressed as V, may be computed from a sum of voltage drops across all elements in a Randles equivalent circuit models depicted in FIG. 1, FIG. 2, and FIG. 3. These elements are voltage drops across all series (V_{S}), double layer (V_{dl∥CT}), and Warburg (V_{W}) elements. V may be expressed as:

V=V_{S}+V_{dl∥CT}+V_{W}

Where V_{S}, V_{dl∥CT}, and V_{W} must be computed as follows:

$${V}_{s} = {iR}_{s} \\ {V}_{dl \vert \vert ct} = {iR}_{ct} ( 1 - {e}^{- \frac{t}{{R}_{ct} {C}_{dl}}} ) \\ {V}_{W} = {iR}_{W} ( 1 - {e}^{- \frac{t}{{R}_{W} {C}_{W}}} )$$

Wherein, V_{w} may be rewritten for every branch, n, of the equivalent R_{w} element as follows:

$${V}_{n} = {iR}_{n} ( 1 - {e}^{- \frac{t}{{R}_{n} {C}_{n}}} )$$

### Wherein:

V_{W}=V₁+V₂+ . . . Vₙ

R_{W} affects C_{W} as follows:

$${C}_{W} = \frac{{c}_{i} {R}_{W}^{2} {F}^{2} Al}{2 {R}_{u} T}$$

Where cᵢ is the ionic concentration of the electrolyte in moles per kilogram of electrolyte, l is the electrode thickness, Rᵤ is the universal gas constant, and T is the temperature of the energy storage device. Additionally:

$${C}_{dl} = \frac{F ρ l}{2 M} ( 1 - ε ) \frac{l}{{l}_{s}}$$

Wherein F is Faraday's constant, ρ is the density of the electrode material, l is the thickness of the electrode, M is the mass of the electrode, ϵ is the porosity of the electrode, and lₛ is the thickness of the separator. All of these variables are constant. Therefore, C_{dl} is a constant and wherein:

$${R}_{ct} = \frac{{R}_{u} T}{{nFi}_{o}}$$

Where Rᵤ is the universal gas constant, n is the number of electrodes per ion (n=1 for lithium), and iₒ is the exchange current density. T is initially the ambient temperature, but is subsequently computed from

$$T = \frac{{α}_{a} nF η}{{R}_{u} ln ( \frac{{i}_{d}}{{i}_{o}} - 1 )}$$

Where i_{d} is current density, or charge or discharge current divided by electrode area. iₒ can be computed as a function of the intercalation rate constant of the electrode material (k), the specific capacitance of the electrode material (C_{b}), αₐ and α_{c}, the concentration in intercalation material of the electrode material (C_{T}), and the ionic concentration that has intercalated into the negative electrode (cₛ) as follows

iₒ=kC_{b}^{a}^{ₐ}(c_{T}−cₛ)^{a}^{ₐ}cₛ^{a}^{_{c}}

In accordance with Fick's second law of diffusion cₛ is computed by

$$\frac{{dc}_{s}}{dt} = \frac{{Dd}^{2} {c}_{s}}{{( dr )}^{2}}$$

which can be simplified to

$${c}_{s} = \int \frac{{D}_{s} {d}^{2} {c}_{s}}{{( dr )}^{2}} dt$$

where Dₛ is the ionic diffusion coefficient, dcₛ is assumed to be 100% intercalation of lithium ions, dr is the thickness of the negative electrode, and dt is the charge time. Dₛ can be found from the equation

$${D}_{s} = \frac{{R}_{u}^{2} {T}^{2}}{2 {n}^{4} {F}^{4} {A}^{2} {c}_{i}^{2} {σ}^{2}}$$

whereby σ is the solid phase conductivity of the ionic material.

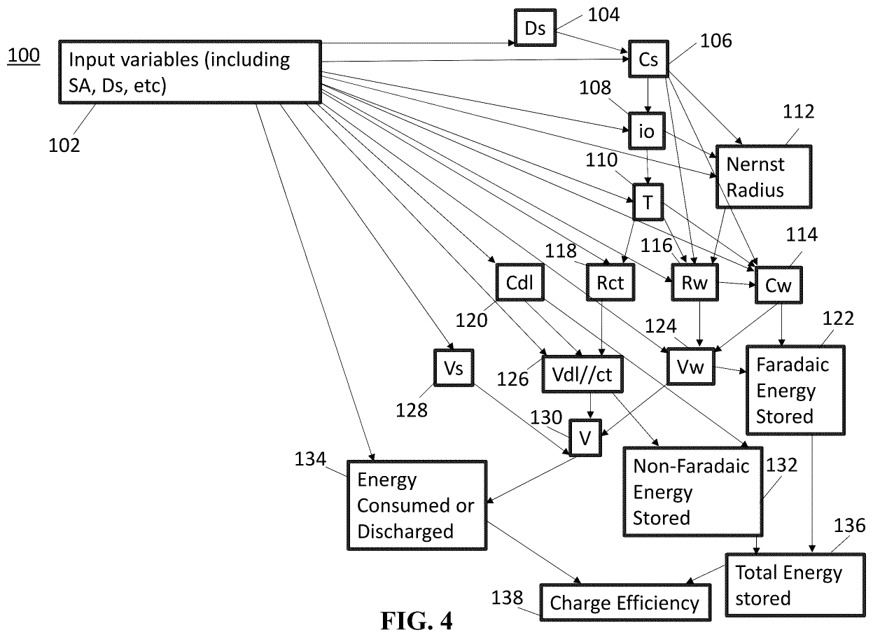

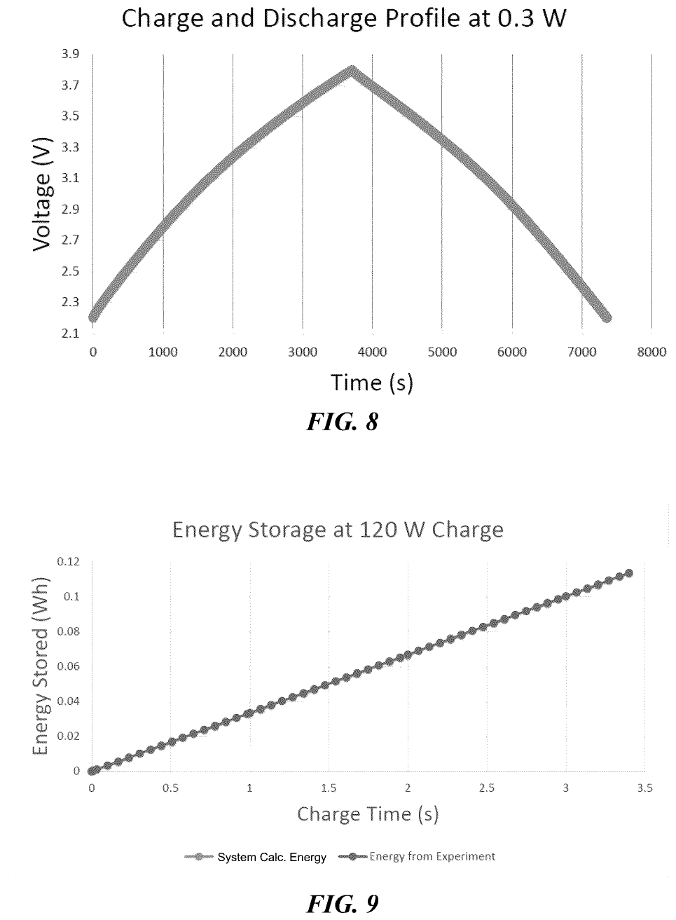

Referring to FIG. 4, a system or method 100 of designing an energy storage device as a function of size, components, and operating conditions may include receiving initial inputs such as, but not limited to, ambient temperature T, electrode density (ρ), active layer porosity (ϵ), metal current collector density, separator thickness (Iₛ), intercalation rate constant (k), specific capacitance of electrode (C_{b}), initial concentration of intercalation material in the electrode material (C_{T}), initial concentration of electrolyte (Cᵢ), effective conductivity of electrode material (σ), specific surface area of the anode (αₐ) and cathode electrodes (α_{c}), effective particle radius (r_{eff}), or Nernst diffusion radius (δ), and an ionic diffusion coefficient (Dₛ) of the energy storage device. The system 100 may utilize initial input 102 to determine the ionic diffusion coefficient (Dₛ) 104. The system 100 may utilize initial input 102 to determine ionic concentration intercalated in a negative electrode (cₛ) 106. The system 100 may determine exchange current density (iₒ) 108 and subsequently operating temperature 110 of the energy storage device. Operating temperature 110 may initially be ambient temperature input into the system but may be continuously recalculated as a function of time and influence subsequent value determinations in steps 104, 106, 108, and 110 according to each respective time step when instantaneous voltage is determined over time. The system 100 may utilize initial input 102 to determine the Nernst diffusion radius 112. The system 100 may subsequently determine Warburg resistance 116, charge transfer resistance 118, and Warburg capacitance 114. The system 100 may determine double layer capacitance 120, and subsequently, determine voltage 126 across charge transfer and double layer elements. Additionally, the system 100 may determine Warburg voltage 124 and instantaneous voltage 130 as a sum of series voltage 128, voltage 126, and Warburg voltage 124 determined at a particular time step. Instantaneous voltage 130 may be displayed as a function of time, as shown in FIG. 8. The system 100 can then determine the Faradaic energy stored 122, the non-Faradaic energy stored 132, the energy consumed or discharged by the energy storage device 134, the total energy stored by the energy storage device 136, and the charge efficiency 138 of the energy storage device.

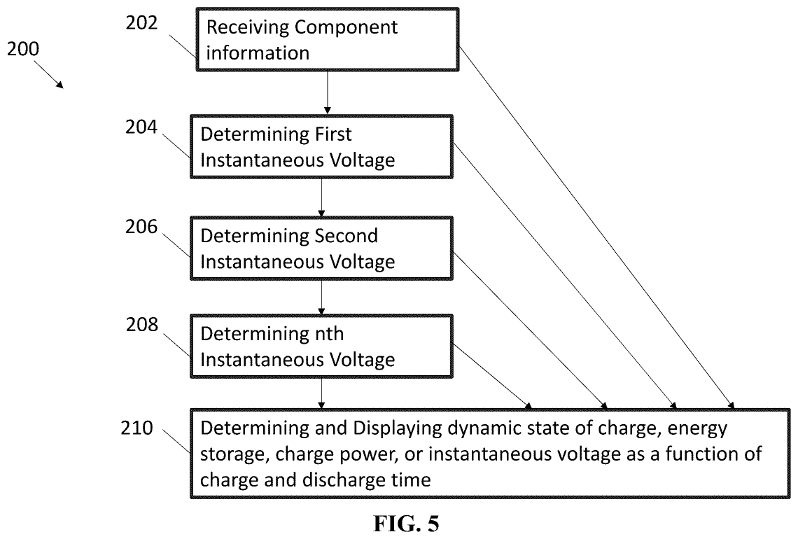

Referring to FIG. 5, a system or method 200 of determining the state of charge in an energy storage device as a function of size, components, and operating conditions may include the first action 202 of receiving component information including at least constituent components. The system may take action 204 to determine a first instantaneous voltage based on the charge or discharge current and any resistance of the energy storage device (e.g., Warburg resistance, charge transfer resistance, series resistance). The system may compensate for charge power or degradation as a function of current and temperature when determining the first instantaneous voltage. The system may take action 206 to determine a second instantaneous voltage based on the charge or discharge current and any resistance of the energy storage device (e.g., Warburg resistance, charge transfer resistance, series resistance). The system may compensate for charge power or degradation as a function of current and temperature when determining the second instantaneous voltage. The system may take action 208 to determine nth instantaneous voltage based on the charge or discharge current and any resistance of the energy storage device (e.g., Warburg resistance, charge transfer resistance, series resistance). The system may compensate for charge power or degradation as a function of current and temperature when determining the nth instantaneous voltage. The system may take action 210 to display any number of variables determined by the system based on the received component information including at least constituent components 202, including, but not limited to, dynamic state of charge, energy storage, energy storage capacity, charge power, instantaneous voltage over time, or any combination thereof.

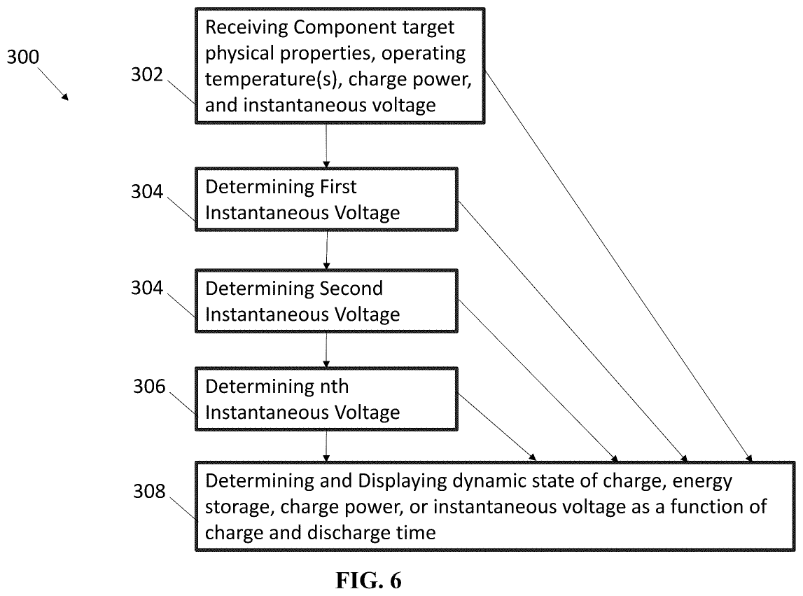

Referring to FIG. 6, a system or method 300 of designing an energy storage device as a function of size, components, and operating conditions may include the first action 302 of receiving energy storage device target physical properties, target operating temperature(s), target charge power, or target instantaneous voltage. The system may take action 304 to determine a first instantaneous voltage based on the charge or discharge current and any resistance of the energy storage device (e.g., Warburg resistance, charge transfer resistance, series resistance). The system may compensate for charge power or degradation as a function of current and temperature when determining the first instantaneous voltage. The system may take action 304 to determine a second instantaneous voltage based on the charge or discharge current and any resistance of the energy storage device (e.g., Warburg resistance, charge transfer resistance, series resistance). The system may compensate for charge power or degradation as a function of current and temperature when determining the second instantaneous voltage. The system may take action 306 to determine nth instantaneous voltage based on the charge or discharge current and any resistance of the energy storage device (e.g., Warburg resistance, charge transfer resistance, series resistance). The system may compensate for charge power or degradation as a function of current and temperature when determining the nth instantaneous voltage. The system may take action 308 to display any number of variables determined by the system based on the received component information including at least constituent components 302, including, but not limited to, dynamic state of charge, energy storage, energy storage capacity, charge power, instantaneous voltage over time, or any combination thereof.

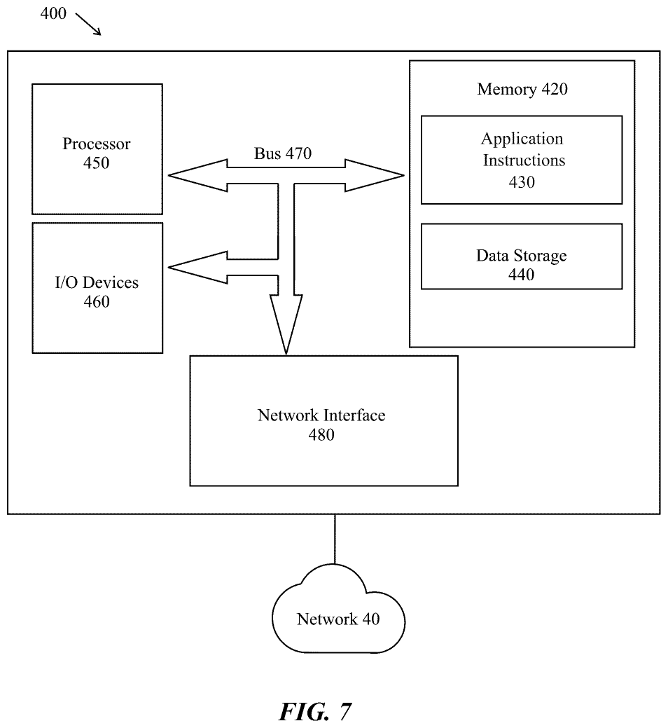

FIG. 7 is a diagram illustrating a non-limiting example of computing device 400 implementing a system for designing an energy storage device as a function of size, components, and operating conditions or target physical properties, target operating temperature(s), target charge power, or target instantaneous voltage and/or implementing a system for determining an energy storage device state of health. The computing device 400 may include a standalone computer or mobile computing device, workstation, network computer, laptop, or the like. The computing device 400 may include a processor 450 coupled to a memory 420 via a bus 470. The processor 450 may be constructed and arranged for the execution of computer readable program instructions including the system for designing an energy storage device 430 and/or the system for determining the energy storage device state of health 430. The bus 470 may be any of several types of bus structures including a memory bus or memory controller, a peripheral bus, and a local bus using any of a variety of bus architectures. The computing device 400 may include various input and output devices 460 in operable communication with the processor 450. The input and output devices 460 may include a variety of devices such as video devices, audio devices, displays, or the like. In some instances, the input and output devices 460 may be separate from the computing device 400. The computing device 400 may include memory 420 which may include computer readable application instructions 430. The memory 420 may include data storage 440 which may include data accessible by the program instructions. Data storage 440 may include a component information database configured to store energy storage device information such as, but not limited to, energy storage device constituent components, or any other information associated with an energy storage device. The computing device 400 may include a network interface 480 constructed and arranged to allow the computing device 400 to communicate with and over a network 40. Various computing devices 400 executing the system for designing an energy storage device 430 and/or the system for determining the energy storage device's state of health may be in operable communication with one another over the network 40.

FIG. 8 depicts a dynamic graph drawn by the system to communicate voltage of an energy storage device as a function of charge and discharge time. FIG. 8 only shows one charge and discharge cycle and does not account for degradation over time.

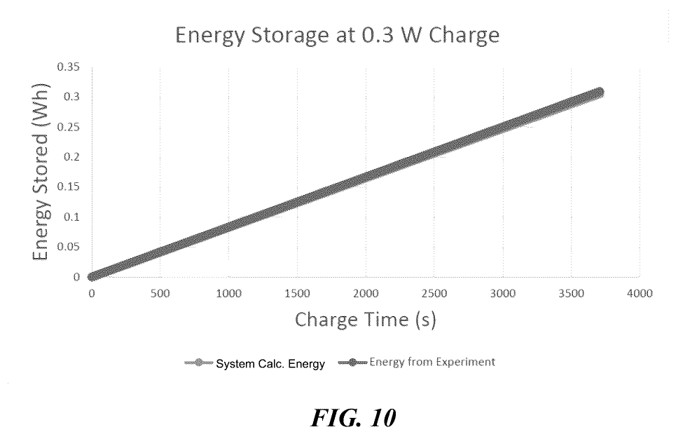

FIGS. 9 and 10 depict dynamic graphs drawn by the system to communicate energy storage of an energy storage device as a function of charge time. FIGS. 9 and 10 only show one charge and discharge cycle and do not account for degradation over time.

The system may be configured to determine the energy stored by a virtual energy storage device and related properties of a to-be-built energy storage device as a function of the anticipated charge or discharge current and the constituent components of the energy storage device. Complex charge or discharge current profiles, like those anticipated in real world operations may be uploaded into the system to predict the virtual energy storage device's performance under those conditions.

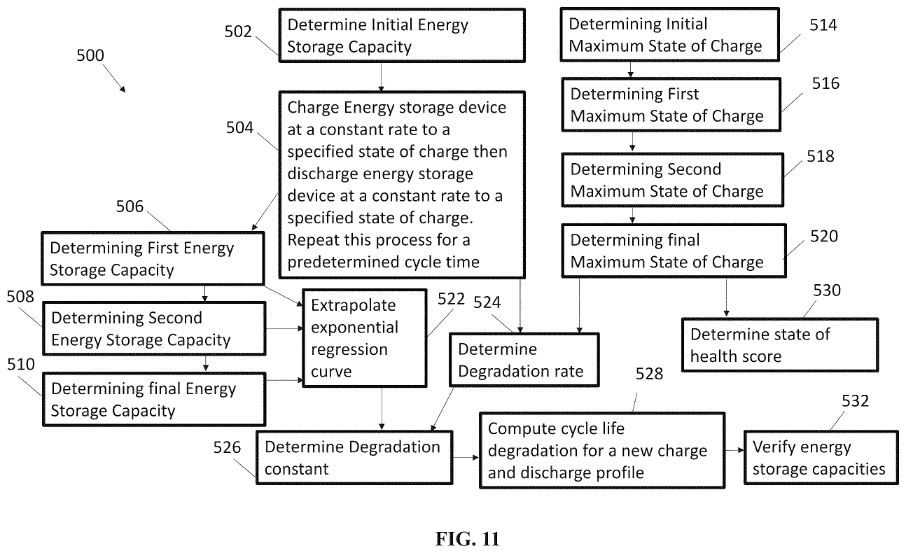

Referring to FIG. 11, a system or method 500 for describing an energy storage device's degradation properties and then predicting its performance under a new use case.

In some embodiments, if the energy storage device includes multiple individual battery cells linked by power electronics hardware or by a power management system, a Randles equivalent circuit model representative of an average battery in the device can be designed, scaled by a multiplier to describe the performance of the energy storage device. The series resistance (Rs) in the Randles equivalent circuit model can be adjusted to account for power electronics hardware losses.

In some embodiments, the system may take action 502 to determine an initial value indicating an initial energy storage capacity of the energy storage device at an initial cycle time (e,g., when the cycle time is zero).

In some embodiments, the system may take action 504 to charge energy storage device at a constant rate to a specified state of charge then discharge energy storage device at a constant rate to a specified state of charge. Repeat this process for a predetermined cycle time. In some embodiments, the system may take action 504 continuously for a predetermined amount of time.

In some embodiments, the system may take action 504 to determine a first energy storage capacity 506 at a first cycle time, the first cycle time being different from the initial cycle time. In some embodiments, the system may take action 504 to determine a second energy storage capacity 508 at a second cycle time, the second cycle time being different from the initial cycle time and the first cycle time.

In some embodiments, the system may take action 510 to determine a final energy storage capacity 510 at a final cycle time, the final cycle time being different from the initial cycle time, the first cycle time, and the second cycle time. In some embodiments, the final cycle time can be an estimated number of cycles in which the energy storage device was charged and discharged. In some embodiments, the system may determine any suitable number of energy storage capacities at respective cycle times. In some embodiments, as the energy storage device is charged and discharged over time, cycle time increases, and the energy storage capacity of the energy storage device can decrease due to a decrease in an electrolyte concentration, a decrease in the electrode effective surface area, or a combination thereof.

In some embodiments the system may determine an initial value 514 indicating an initial maximum state of charge of the energy storage device at the initial cycle time. In some embodiments, the initial value indicating the maximum state of charge can be a value that indicates an initial electrolyte concentration in the energy storage device at the initial cycle time since, for example, the initial maximum state of charge can be based at least in part on the initial electrolyte concentration. In some embodiments, the initial value indicating the initial maximum state of charge can be a value that indicates an initial electrode effective surface area since, for example, the initial maximum state of charge can be based at least in part on the initial electrode effective surface area (e.g., which can be approximately the same as the electrode specific surface area).

In some embodiments the system may determine a first value 516 indicating a first maximum state of charge of the energy storage device at the first cycle time. In some embodiments, the first value indicating the maximum state of charge can be a value that indicates a first electrolyte concentration in the energy storage device at the initial cycle time since, for example, the first maximum state of charge can be based at least in part on the first electrolyte concentration. In some embodiments, the first value indicating the first maximum state of charge can be a value that indicates a first electrode effective surface area since, for example, the first maximum state of charge can be based at least in part on the first electrode effective surface area.

In some embodiments the system may determine a second value 518 indicating a second maximum state of charge of the energy storage device at the second cycle time. In some embodiments, the second value indicating the maximum state of charge can be a value that indicates a second electrolyte concentration in the energy storage device at the second cycle time since, for example, the second maximum state of charge can be based at least in part on the second electrolyte concentration. In some embodiments, the second value indicating the second maximum state of charge can be a value that indicates a second electrode effective surface area since, for example, the second maximum state of charge can be based at least in part on the second electrode effective surface area.

In some embodiments the system may determine a final value 520 indicating a final maximum state of charge of the energy storage device at the final cycle time. In some embodiments, the final value indicating the maximum state of charge can be a value that indicates a final electrolyte concentration in the energy storage device at the final cycle time since, for example, the final maximum state of charge can be based at least in part on the final electrolyte concentration. In some embodiments, the final value indicating the final maximum state of charge can be a value that indicates a final electrode effective surface area since, for example, the final maximum state of charge can be based at least in part on the final electrode effective surface area.

In some embodiments, the first value indicating the initial maximum state of charge can be based at least on the initial value indicating the initial maximum state of charge, the initial value indicating the initial energy storage capacity, the first value indicating the first energy storage capacity, or any combination thereof.

In some embodiments, the second value indicating the second maximum state of charge can be based at least on the initial value indicating the initial maximum state of charge, the initial value indicating the initial energy storage capacity, the second value indicating the second energy storage capacity, or any combination thereof.

In some embodiments, the final value indicating the final maximum state of charge can be based at least on the initial value indicating the initial maximum state of charge, the initial value indicating the initial energy storage capacity, the final value indicating the final energy storage capacity, or any combination thereof.

In some embodiments, the system may take action 524 to determine a degradation rate 524 indicating an expected degradation of the energy storage device per cycle time unit (e.g., cycle minutes, cycle hours, etc. or cycle count). In some embodiments, the degradation rate 524 can be based at least on a first difference between the first electrolyte concentration and the second electrolyte concentration, and a second difference between the first cycle time and the second cycle time, as in:

$${D}_{T} = \frac{{C}_{i} - {C}_{f}}{t}$$

In some embodiments, the degradation rate can indicate an expected decrease of the electrolyte concentration in the energy storage device per cycle time unit (e.g., minutes, hours, etc. or cycle count) during which the energy storage device is charged and discharged. The experimental data gives values of Cᵢ, C_{f}, and t (i.e., cycle time). These values can compute D_{T}.

In some embodiments, the system may take action 522 to perform a regression analysis (e.g., an exponential regression analysis) based at least on any energy storage capacities determined and their respective cycle times. In some embodiments, the system can plot any energy stored or released during a charge and discharge cycle.

The regression analysis can be performed to generate an exponential equation of the form

y=A_{D}e^{-bt}

combining the results of the regression analysis with the Arrhenius equation

$${D}_{T} = {A}_{D} {e}^{\frac{- {E}_{a}}{RT}}$$

As the degradation analysis has provided a value for A_{D}, R is the universal gas constant, T is the ambient temperature, and Eₐ is the energy storage device's storage reaction's activation energy.

In some embodiments, the system can take action 526 to determine the degradation constant b as follows:

$$b = \frac{{E}_{a}}{RTt}$$

In some embodiments, the system can determine the cycle life degradation 528 as tib.

In some embodiments, the system can determine a change in C_{f} based at least on the cycle life degradation 528 and/or the degradation constant b as follows:

C_{f}=Cᵢ−tib

or

$${C}_{f} = {C}_{i} - i \frac{{E}_{a}}{RT}$$

In some embodiments, the system may determine an estimated maximum cycle time for the energy storage device based at least on the degradation rate, the degradation constant, any suitable threshold, or any combination thereof. In some embodiments, the system can determine a cycle time after which the electrolyte concentration in the energy storage device decreases below an electrolyte concentration threshold.

In some embodiments, the system may take action 530 to determine a score indicating a state of health of the energy storage device. In some embodiments, the score indicating the state of health of the energy storage device can be based at least on the first electrolyte concentration, the second electrolyte concentration, or a combination thereof. In some embodiments, the score indicating the state of health of the energy storage device can be based at least on a ratio between the first electrolyte concentration and the second electrolyte concentration. In some embodiments, the score indicating the state of health of the energy storage device can be based at least on a ratio between the first electrode effective surface area and the second electrode effective surface area. In some embodiments, if the score is below a threshold, the system may indicate failure of the energy storage device or recommend replacing the energy storage device.

In some embodiments, the system may take action 532 to verify any energy storage capacity of the energy storage device. In some embodiments, any energy storage capacity of the energy storage device can be verified by measuring the energy used to charge the energy storage device or the energy discharged by the energy storage device, and comparing the measured energy to the determined energy storage capacity. In some embodiments, the system may take any suitable actions to display any values determined in method 500.

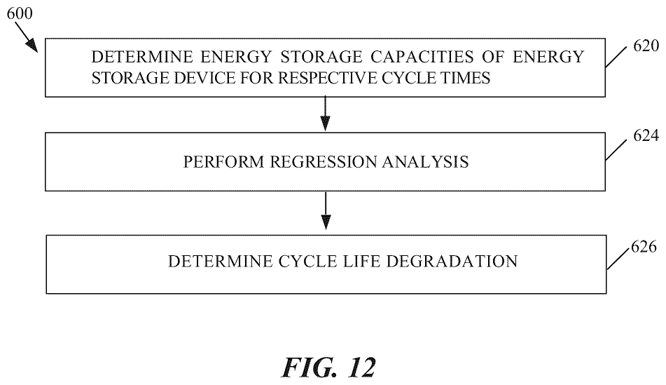

Referring to FIG. 12, a system or method 600 for performing regression analysis can take action 620 to determine a plurality of energy storage capacities of an energy storage device for respective cycle times (e.g., cycle minutes, cycle hours, etc. or cycle counts).

In some embodiments, the system may take action 624 to perform a regression analysis based at least on the energy storage capacities, the respective cycle times, or any combination thereof. In some embodiments, the regression analysis can be an exponential regression analysis performed to determine an expected energy storage capacity based at least on a selected cycle time.

In some embodiments, the system may take action 626 to determine a cycle life degradation. The cycle life degradation can be determined based at least on a degradation rate, a degradation constant, a charge or discharge current, cycle time, a calendar time, or any combination thereof.

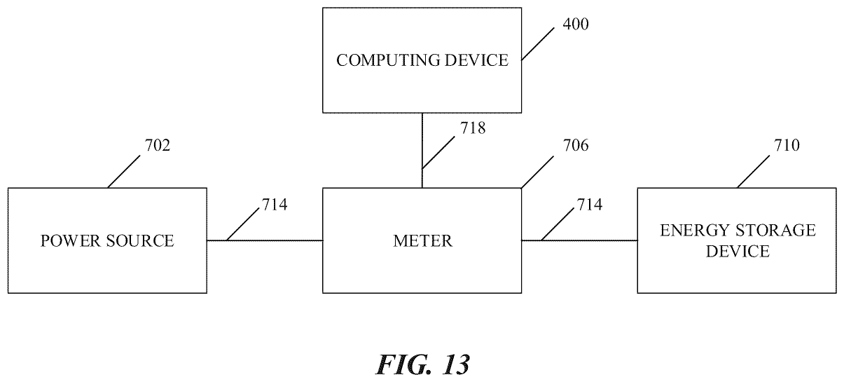

Referring to FIG. 13, a power source 702 can be electrically connected, via at least electrical connections 714, to an energy storage device 710. In some embodiments, the power source 702 can be constructed and arranged to charge the energy storage device 710. In some embodiments, an electricity meter 706 can be electrically connected, via at least electrical connections 714, between the power source 702 and the energy storage device 710. The electricity meter 706 can be constructed and arranged to measure the amount of energy provided by the power source 702 to charge the energy storage device 710. A computing device 400 can be communicatively connected, via connection 718 (e.g., an electrical connection, an optical connection, etc.), to the electricity meter 706 to determine an energy storage capacity of the energy storage device 710 based at least on the amount of energy provided by the power source 702 to charge the energy storage device 710.

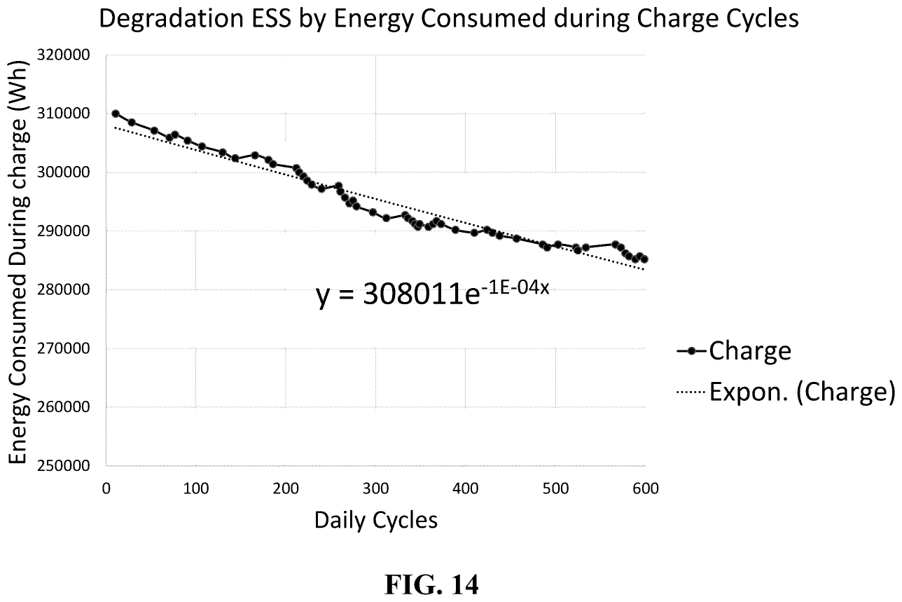

FIG. 14 depicts a dynamic graph drawn by the system to communicate energy storage capacities of an energy storage device as a function of cycle count and a fitted exponential curve to perform an exponential regression analysis.

The following description of variants is only illustrative of components, elements, acts, products, and methods considered to be within the scope of the invention and are not in any way intended to limit such scope by what is specifically disclosed or not expressly set forth. The components, elements, acts, products, and methods as described herein may be combined and rearranged other than as expressly described herein and are still considered to be within the scope of the invention.

According to variation 1, a system for determining an energy storage device state of health can include: memory; and one or more processors configured at least to: determine a first cycle time for an energy storage device; determine a first value indicating a first energy storage capacity for the energy storage device at the first cycle time; determine a first electrolyte concentration for the energy storage device at the first cycle time; determine a second cycle time for the energy storage device, the second cycle time being different than the first cycle time; determine a second value indicating a second energy storage capacity for the energy storage device at the second cycle time; determine a second electrolyte concentration for the energy storage device based at least on: the first electrolyte concentration; the first value indicating the first energy storage capacity; and the second value indicating the second energy storage capacity; and determine a degradation rate indicating an expected degradation of the energy storage device per cycle time unit based at least on: a first difference between the first electrolyte concentration and the second electrolyte concentration; and a second difference between the first cycle time and the second cycle time.

Variation 2 can include the system of variation 1, wherein the one or more processors are further configured to: determine a score indicating a state of health of the energy storage device based at least on: the first electrolyte concentration; and the second electrolyte concentration.

Variation 3 can include the system of variation 1, wherein the one or more processors are further configured to: determine an estimated maximum count of cycles for the energy storage device based at least on the degradation rate.

Variation 4 can include the system of variation 1, wherein determining the second value indicating the second energy storage capacity for the energy storage device at the second cycle time comprises performing a regression analysis to determine the second value indicating the second energy storage capacity.

Variation 5 can include the system of variation 1, wherein: the first cycle time is a first count of cycles or a first amount of time in which the energy storage device was cycled; and the second cycle time is a second count of cycles or a second amount of time in which the energy storage device was cycled.

Variation 6 can include the system of variation 2, wherein the score indicating the state of health of the energy storage device is based at least on a ratio between the first electrolyte concentration and the second electrolyte concentration.

Variation 7 can include the system of variation 1, wherein the one or more processors are further configured to: determine a first electrode effective surface area for the energy storage device at the first cycle time; determine a second electrode effective surface area for the energy storage device based at least on: the first electrode effective surface area; the first value indicating the first energy storage capacity; and the second value indicating the second energy storage capacity; and determine a second score indicating a second state of health of the energy storage device based at least on: a ratio between the first electrode effective surface area and the second electrode effective surface area.

According to variation 8, a method for determining an energy storage device state of health can include: determining a first cycle time for an energy storage device; determining a first value indicating a first energy storage capacity for the energy storage device at the first cycle time; determining a first electrolyte concentration for the energy storage device at the first cycle time; determining a second cycle time for the energy storage device, the second cycle time being different than the first cycle time; determining a second value indicating a second energy storage capacity for the energy storage device at the second cycle time; determining a second electrolyte concentration for the energy storage device based at least on: the first electrolyte concentration; the first value indicating the first energy storage capacity; and the second value indicating the second energy storage capacity; and determining a degradation rate indicating an expected degradation of the energy storage device per cycle time unit based at least on: a first difference between the first electrolyte concentration and the second electrolyte concentration; and a second difference between the first cycle time and the second cycle time.

Variation 9 can include the method of variation 8, further comprising: determining a score indicating a state of health of the energy storage device based at least on: the first electrolyte concentration; and the second electrolyte concentration.

Variation 10 can include the method of variation 8, further comprising: determining an estimated maximum count of cycles for the energy storage device based at least on the degradation rate.

Variation 11 can include the method of variation 8, wherein determining the second value indicating the second energy storage capacity for the energy storage device at the second cycle time comprises performing a regression analysis to determine the second value indicating the second energy storage capacity.

Variation 12 can include the method of variation 8, wherein: the first cycle time is a first count of cycles or a first amount of time in which the energy storage device was cycled; and the second cycle time is a second count of cycles or a second amount of time in which the energy storage device was cycled.

Variation 13 can include the method of variation 9, wherein the score indicating the state of health of the energy storage device is based at least on a ratio between the first electrolyte concentration and the second electrolyte concentration.

Variation 14 can include the method of variation 8, further comprising: determining a first electrode effective surface area for the energy storage device at the first cycle time; determining a second electrode effective surface area for the energy storage device based at least on: the first electrode effective surface area; the first value indicating the first energy storage capacity; and the second value indicating the second energy storage capacity; and determining a second score indicating a second state of health of the energy storage device based at least on: a ratio between the first electrode effective surface area and the second electrode effective surface area.

According to variation 15, a non-transitory computer-readable medium can comprise instructions, that when executed by one or more processors, causes the one or more processors to perform a method for determining an energy storage device state of health, the method comprising determining a first cycle time for an energy storage device; determining a first value indicating a first energy storage capacity for the energy storage device at the first cycle time; determining a first electrolyte concentration for the energy storage device at the first cycle time; determining a second cycle time for the energy storage device, the second cycle time being different than the first cycle time; determining a second value indicating a second energy storage capacity for the energy storage device at the second cycle time; determining a second electrolyte concentration for the energy storage device based at least on: the first electrolyte concentration; the first value indicating the first energy storage capacity; and the second value indicating the second energy storage capacity; and determining a degradation rate indicating an expected degradation of the energy storage device per cycle time unit based at least on: a first difference between the first electrolyte concentration and the second electrolyte concentration; and a second difference between the first cycle time and the second cycle time.

Variation 16 can include the non-transitory computer-readable medium of variation 15, wherein the method further comprises: determining a score indicating a state of health of the energy storage device based at least on: the first electrolyte concentration; and the second electrolyte concentration.

Variation 17 can include the non-transitory computer-readable medium of variation 15, wherein the method further comprises: determining an estimated maximum count of cycles for the energy storage device based at least on the degradation rate.

Variation 18 can include the non-transitory computer-readable medium of variation 15, wherein: the first cycle time is a first count of cycles or a first amount of time in which the energy storage device was cycled; and the second cycle time is a second count of cycles or a second amount of time in which the energy storage device was cycled.

Variation 19 can include the non-transitory computer-readable medium of variation 16, wherein the score indicating the state of health of the energy storage device is based at least on a ratio between the first electrolyte concentration and the second electrolyte concentration.

Variation 20 can include the non-transitory computer-readable medium of variation 15, wherein the method further comprises: determining a first electrode effective surface area for the energy storage device at the first cycle time; determining a second electrode effective surface area for the energy storage device based at least on: the first electrode effective surface area; the first value indicating the first energy storage capacity; and the second value indicating the second energy storage capacity; and determining a second score indicating a second state of health of the energy storage device based at least on: a ratio between the first electrode effective surface area and the second electrode effective surface area.

According to variation 21, a method of predicting degradation in an energy storage device can comprise: repeating, for each charge or discharge cycle, the steps of: generating a Randles equivalent circuit, that models how the operating current interacts with at least one of an electrolyte, lithium ions, or electrodes in at least one of a LIB, LIC, or hybrid of the two; and modeling, via an Arrhenius equation, irregular charge or discharge profiles of at least one of a LIB, LIC, or hybrid over time.

According to variation 22, a method of predicting degradation in an energy storage device can comprise: discretizing a charge or discharge cycle into time steps: generating a Randles equivalent circuit that models how the operating current interacts with at least one of an electrolyte, lithium ions, or electrodes in at least one of a LIB, LIC, or hybrid of the two; and modeling, via an Arrhenius equation, irregular charge or discharge profiles of at least one of a LIB, LIC, or hybrid over time.

According to variation 23, a method of predicting degradation in an energy storage device can comprise: repeating, for each charge or discharge cycle, the steps of: generating a Randles equivalent circuit, that models how the operating current interacts with at least one of an electrolyte, lithium ions, or electrodes in at least one of a LIB, LIC, or hybrid of the two; and modeling, via an Arrhenius equation, changes to electrolyte concentration of at least one of a LIB, LIC, or hybrid over time.

According to variation 24, a method of predicting degradation in an energy storage device can comprise: discretizing a charge or discharge cycle into time steps: generating a Randles equivalent circuit, that models how the operating current interacts with at least one of an electrolyte, lithium ions, or electrodes in at least one of a LIB, LIC, or hybrid of the two; and modeling, via an Arrhenius equation, changes to the electrode's material's capacity to store energy-carrying ions in at least one of a LIB, LIC, or hybrid over time.

According to variation 25, a method of predicting degradation in an energy storage device can comprise: discretizing a charge or discharge cycle into time steps: generating a Randles equivalent circuit, that models how the operating current interacts with at least one of an electrolyte, lithium ions, or electrodes in at least one of a LIB, LIC, or hybrid of the two; and modeling, via an Arrhenius equation, both changes to electrolyte concentration and changes to the electrode materials' capacity to store energy-carrying ions in at least one of a LIB, LIC, or hybrid over time.

According to variation 26, a method of performing a regression analysis on existing battery performance data to generate an Arrhenius equation to describe a battery's degradation is disclosed. Then using this Arrhenius equation to predict the battery's degradation.

According to variation 27, a method of predicting an energy storage system (ESS) comprised of multiple individual battery cells linked by power electronics hardware can include designing a Randles Equivalent Circuit Model representative of an average battery in the system, scaled by a multiplier proportionally increasing electrode area (and by extension effective surface area), volume, and mass to describe the performance of the larger ESS and by adjusting the series resistance (Rs) in a Randles Equivalent Circuit Model to account for power electronics hardware losses.

According to variation 28, a method of predicting an energy storage system (ESS) comprised of multiple individual battery cells linked by a battery management system (BMS) can include designing a Randles Equivalent Circuit Model representative of an average battery in the system, scaled by a multiplier to describe the performance of the larger ESS, and adjusting series resistance (Rs) to account for power electronics hardware losses.

Many different embodiments have been disclosed herein, in connection with the above description and the drawings. It will be understood that it would be unduly repetitious and obfuscating to describe and illustrate every combination and subcombination of these embodiments. Accordingly, all embodiments can be combined in any way and/or combination, and the present specification, including the drawings, shall be construed to constitute a complete written description of all combinations and subcombinations of the embodiments described herein, and of the manner and process of making and using them, and shall support claims to any such combination or subcombination.

An equivalent substitution of two or more elements can be made for any one of the elements in the claims below or that a single element can be substituted for two or more elements in a claim. Although elements can be described above as acting in certain combinations and even may have been initially claimed as such, it is to be expressly understood that one or more elements from a claimed combination can in some cases be excised from the combination and that the claimed combination can be directed to a subcombination or variation of a subcombination.

It will be appreciated by persons skilled in the art that the present embodiment is not limited to what has been particularly shown and described hereinabove. A variety of modifications and variations are possible in light of the above teachings without departing from the following claims.

What is claimed is:

1. A system for determining an energy storage device state of health, comprising:
memory; and
one or more processors configured at least to:
determine a first cycle time for an energy storage device;
determine a first value indicating a first energy storage capacity for the energy storage device at the first cycle time;
determine a first electrolyte concentration for the energy storage device at the first cycle time;
determine a second cycle time for the energy storage device, the second cycle time being different than the first cycle time;
determine a second value indicating a second energy storage capacity for the energy storage device at the second cycle time;
determine a second electrolyte concentration for the energy storage device based at least on:
the first electrolyte concentration;
the first value indicating the first energy storage capacity; and
the second value indicating the second energy storage capacity; and
determine a degradation rate indicating an expected degradation of the energy storage device per cycle time unit based at least on:
a first difference between the first electrolyte concentration and the second electrolyte concentration; and
a second difference between the first cycle time and the second cycle time.

2. The system of claim 1, wherein the one or more processors are further configured to:
determine a score indicating a state of health of the energy storage device based at least on:
the first electrolyte concentration; and
the second electrolyte concentration.

3. The system of claim 1, wherein the one or more processors are further configured to:
determine an estimated maximum count of cycles for the energy storage device based at least on the degradation rate.

4. The system of claim 1, wherein determining the second value indicating the second energy storage capacity for the energy storage device at the second cycle time comprises performing a regression analysis to determine the second value indicating the second energy storage capacity.

5. The system of claim 1, wherein:
the first cycle time is a first count of cycles or a first amount of time in which the energy storage device was cycled; and
the second cycle time is a second count of cycles or a second amount of time in which the energy storage device was cycled.

6. The system of claim 2, wherein the score indicating the state of health of the energy storage device is based at least on a ratio between the first electrolyte concentration and the second electrolyte concentration.

7. The system of claim 1, wherein the one or more processors are further configured to:
determine a first electrode effective surface area for the energy storage device at the first cycle time;
determine a second electrode effective surface area for the energy storage device based at least on:
the first electrode effective surface area;
the first value indicating the first energy storage capacity; and
the second value indicating the second energy storage capacity; and
determine a second score indicating a second state of health of the energy storage device based at least on:
a ratio between the first electrode effective surface area and the second electrode effective surface area.

8. A method for determining an energy storage device state of health, comprising:
determining a first cycle time for an energy storage device;
determining a first value indicating a first energy storage capacity for the energy storage device at the first cycle time;
determining a first electrolyte concentration for the energy storage device at the first cycle time;
determining a second cycle time for the energy storage device, the second cycle time being different than the first cycle time;
determining a second value indicating a second energy storage capacity for the energy storage device at the second cycle time;
determining a second electrolyte concentration for the energy storage device based at least on:
the first electrolyte concentration;
the first value indicating the first energy storage capacity; and
the second value indicating the second energy storage capacity; and
determining a degradation rate indicating an expected degradation of the energy storage device per cycle time unit based at least on:
a first difference between the first electrolyte concentration and the second electrolyte concentration; and
a second difference between the first cycle time and the second cycle time. on:

9. The method of claim 8, further comprising:
determining a score indicating a state of health of the energy storage device based at least on:
the first electrolyte concentration; and
the second electrolyte concentration.

10. The method of claim 8, further comprising:
determining an estimated maximum count of cycles for the energy storage device based at least on the degradation rate.

11. The method of claim 8, wherein determining the second value indicating the second energy storage capacity for the energy storage device at the second cycle time comprises performing a regression analysis to determine the second value indicating the second energy storage capacity.

12. The method of claim 8, wherein:
the first cycle time is a first count of cycles or a first amount of time in which the energy storage device was cycled; and
the second cycle time is a second count of cycles or a second amount of time in which the energy storage device was cycled.

13. The method of claim 9, wherein the score indicating the state of health of the energy storage device is based at least on a ratio between the first electrolyte concentration and the second electrolyte concentration.

14. The method of claim 8, further comprising:
determining a first electrode effective surface area for the energy storage device at the first cycle time;
determining a second electrode effective surface area for the energy storage device based at least on:
the first electrode effective surface area;
the first value indicating the first energy storage capacity; and
the second value indicating the second energy storage capacity; and
determining a second score indicating a second state of health of the energy storage device based at least on:
a ratio between the first electrode effective surface area and the second electrode effective surface area.

15. A non-transitory computer-readable medium comprising instructions, that when executed by one or more processors, causes the one or more processors to perform a method for determining an energy storage device state of health, the method comprising
determining a first cycle time for an energy storage device;
determining a first value indicating a first energy storage capacity for the energy storage device at the first cycle time;
determining a first electrolyte concentration for the energy storage device at the first cycle time;
determining a second cycle time for the energy storage device, the second cycle time being different than the first cycle time;
determining a second value indicating a second energy storage capacity for the energy storage device at the second cycle time;
determining a second electrolyte concentration for the energy storage device based at least on:
the first electrolyte concentration;
the first value indicating the first energy storage capacity; and
the second value indicating the second energy storage capacity; and
determining a degradation rate indicating an expected degradation of the energy storage device per cycle time unit based at least on:
a first difference between the first electrolyte concentration and the second electrolyte concentration; and
a second difference between the first cycle time and the second cycle time.

16. The non-transitory computer-readable medium of claim 15, wherein the method further comprises:
determining a score indicating a state of health of the energy storage device based at least on:
the first electrolyte concentration; and
the second electrolyte concentration.

17. The non-transitory computer-readable medium of claim 15, wherein the method further comprises:
determining an estimated maximum count of cycles for the energy storage device based at least on the degradation rate.

18. The non-transitory computer-readable medium of claim 15, wherein:
the first cycle time is a first count of cycles or a first amount of time in which the energy storage device was cycled; and
the second cycle time is a second count of cycles or a second amount of time in which the energy storage device was cycled.

19. The non-transitory computer-readable medium of claim 16, wherein the score indicating the state of health of the energy storage device is based at least on a ratio between the first electrolyte concentration and the second electrolyte concentration.

20. The non-transitory computer-readable medium of claim 15, wherein the method further comprises:
determining a first electrode effective surface area for the energy storage device at the first cycle time;
determining a second electrode effective surface area for the energy storage device based at least on:
the first electrode effective surface area;
the first value indicating the first energy storage capacity; and
the second value indicating the second energy storage capacity; and
determining a second score indicating a second state of health of the energy storage device based at least on:
a ratio between the first electrode effective surface area and the second electrode effective surface area.
